(19) United States
(12) Patent Application Publication
(10) Pub. No.: US 2022/0243357 A1
(43) Pub. Date: Aug. 4, 2022

(54) PRODUCTION APPARATUS FOR GALLIUM OXIDE CRYSTAL AND PRODUCTION METHOD FOR GALLIUM OXIDE CRYSTAL

(71) Applicants: Fujikoshi Machinery Corp., Nagano (JP); SHINSHU UNIVERSITY, Nagano (JP)

(72) Inventors: Keigo HOSHIKAWA, Nagano (JP); Toshinori TAISHI, Nagano (JP); Takumi KOBAYASHI, Nagano (JP); Yoshio OTSUKA, Nagano (JP)

(21) Appl. No.: 17/533,377

(22) Filed: Nov. 23, 2021

(30) Foreign Application Priority Data
Jan. 29, 2021 (JP) 2021-013095

(51) Int. Cl. C30B 11/00; C30B 29/16

(52) U.S. Cl. CPC C30B 11/003; C30B 29/16

(57) ABSTRACT

There is provided a production apparatus for a gallium oxide crystal using the vertical Bridgman method and a production method using the production apparatus. A production apparatus for a gallium oxide crystal using a vertical Bridgman method including: a furnace body formed of a heat resistant material; a crucible shaft freely movable vertically, being extended in the furnace body, and penetrating through a bottom portion of the furnace body in the vertical direction; a crucible for housing a material of a gallium oxide crystal, being disposed on the crucible shaft; a body heater for heating the crucible, being disposed around a periphery of the crucible; and an annealing chamber for annealing the crucible, being disposed under the furnace body, and being connected to a furnace space in the furnace body.

### CROSS-REFERENCE TO RELATED APPLICATION

This application is based upon and claims the benefit of priority of the prior Japanese Patent Application No. 2021-013095, filed on Jan. 29, 2021, and the entire contents of which are incorporated herein by reference.

### TECHNICAL FIELD

The present invention relates to a production apparatus for a gallium oxide crystal and a production method for a gallium oxide crystal.

### BACKGROUND ART

As an apparatus for producing a single crystal of gallium oxide (which may be hereinafter referred to as a “gallium oxide crystal” in some cases) receiving attention as a wide gap semiconductor for power devices, a production apparatus for a gallium oxide crystal using the VB method (vertical Bridgman method) has been known (see PTL 1: JP-A-2017-193466).

The VB method uses a vertical temperature gradient. Specifically, in the production apparatus for a gallium oxide crystal described in PTL 1, a crucible having a material of a gallium oxide crystal (crystal material) housed therein is disposed on a crucible shaft freely movable vertically in a furnace space of a furnace body. Plural heaters extended in the vertical direction are disposed around the crucible. According to the structure, a temperature gradient in the vertical direction with a higher temperature in the upper portion and a lower temperature in the lower portion is provided in the vicinity of the crucible in the furnace space. In heating the crucible with the heaters, the crystal material is melted. The crucible is then descended through the crucible shaft to crystallize the molten material from the lower side, resulting in a gallium oxide crystal.

A resistance heater may be used as the heater. The resistance heater includes a heating part and a conductive part formed of the same material or of substantially the same material connected to each other through welding or the like, and is constituted to have a higher electric resistance of the heating part than the conductive part by forming the heating part to have a smaller diameter than the conductive part. According to the structure, the heating part is electrified through the conductive part connected to an external electric power source, so that the heating part is heated to a high temperature for heating the crucible. As for the material applied to the resistance heater, for example, molybdenum disilicate (MoSi₂) having a good conductivity, a high melting point, and oxidation resistance, or the like has been used.

### SUMMARY OF INVENTION

### Technical Problem

However, the resistance heater formed of MoSi₂ after once heating to around 1,800° C. tends to cause cracks and breakage of the heater due to the difference in thermal expansion coefficient between the SiO₂ coating formed on the surface thereof and MoSi₂, and therefore cannot be cooled to room temperature in some cases. Accordingly, the heater is restricted to cool to approximately 1,100° C., and the crucible (gallium oxide crystal) is taken out from the furnace body at approximately 1,100° C. In the ordinary procedure, in this case, the crucible (gallium oxide crystal) is taken out from the furnace body by withdrawing the crucible along with the crucible shaft supporting the crucible from the bottom portion of the furnace body.

However, in the ordinary procedure, the gallium oxide crystal at the temperature inside the furnace, i.e., 1,000° C. to 1,500° C., is exposed directly to room temperature around 25° C., which results in a concern of cracks and breakage of the crystal due to the thermal damage caused by quenching. Furthermore, the speed of the downward withdrawal of the crucible (crystal) is increased for reducing the temperature difference in the vertical direction of the crucible (crystal), which even more results in quenching of the crucible (crystal), and in a concern of further deterioration of the crystal quality. It is considered that the crystal quality is largely affected thereby in the case where the size of the formed crystal is increased in the future, and therefore there is an increasing demand of the structure capable of stably taking out the formed crystal to the outside of the apparatus while retaining the prescribed temperature in the furnace space.

### Solution to Problem

The present invention has been made in view of the circumstances, and one or more aspects thereof are directed to a production apparatus for a gallium oxide crystal using the vertical Bridgman method that is capable of stably taking out a gallium oxide crystal to the outside of the apparatus by preventing the deterioration of the crystal quality due to quenching of the crucible while retaining the prescribed temperature in the furnace space, and a production method for a gallium oxide crystal using the apparatus.

One or more aspects of the present invention will be described below.

A production apparatus for a gallium oxide crystal according to one aspect of the present invention is a production apparatus for a gallium oxide crystal using a vertical Bridgman method including:

a furnace body formed of a heat resistant material;

a crucible shaft freely movable vertically, being extended in the furnace body, and penetrating through a bottom portion of the furnace body in the vertical direction;

a crucible for housing a material of a gallium oxide crystal, being disposed on the crucible shaft;

a body heater for heating the crucible, being disposed around a periphery of the crucible; and

an annealing chamber for annealing the crucible, being disposed under the furnace body, and being connected to a furnace space in the furnace body.

According to the aspect, the crucible can be descended through the crucible shaft and carried into the annealing chamber connected to the lower portion of the furnace space, while retaining the prescribed temperature in the furnace space, and then the crucible (gallium oxide crystal) after annealing can be taken out to the outside the apparatus. Accordingly, cracks and breakage of the crystal due to quenching can be prevented.

It is preferred that the production apparatus further includes an annealing heater for annealing the crucible, which is disposed in the annealing chamber. According to the structure, the temperature difference between the furnace space and the annealing chamber can be reduced to prevent the quenching of the crucible carried into the annealing chamber, and simultaneously the crucible (gallium oxide crystal) can be stably annealed at a target rate in the annealing chamber.

The annealing heater may be a resistance heater formed of a material having heat resistance to 1,500° C. to 1,700° C. The body heater may be a resistance heater formed of a material having heat resistance to 1,800° C. to 1,900° C.

A production apparatus for a gallium oxide crystal according to another aspect of the present invention is a production apparatus for a gallium oxide crystal using a vertical Bridgman method including:

a furnace body formed of a heat resistant material;

a crucible shaft freely movable vertically, being extended in the furnace body, and penetrating through a bottom portion of the furnace body in the vertical direction;

a crucible for housing a material of a gallium oxide crystal, being disposed on the crucible shaft;

a body heater for heating the crucible, being disposed around a periphery of the crucible;

an annealing chamber for annealing the crucible, being disposed in a lower portion of a furnace space in the furnace body; and

an annealing heater for annealing the crucible, being disposed in the annealing chamber.

According to the aspect, the crucible can be descended through the crucible shaft and carried into the annealing chamber disposed in the lower portion of the furnace space, while retaining the prescribed temperature in the furnace space. The annealing heater is provided in the annealing chamber in addition to the body heater, and thereby the crucible (gallium oxide crystal) can be stably annealed while retaining the prescribed temperature in the furnace space (except for the annealing chamber). Accordingly, the gallium oxide crystal can be stably taken out to the outside the apparatus by preventing cracks and breakage of the crystal due to quenching of the crucible.

A production method for a gallium oxide crystal according to one aspect of the present invention is a production method for a gallium oxide crystal using a production apparatus for a gallium oxide crystal using a vertical Bridgman method. Specifically, the production method includes:

in a furnace space of a furnace body, heating a crucible housing a material of a gallium oxide crystal to a temperature exceeding 1,795° C. to melt the material of a gallium oxide crystal, and then descending the crucible to grow a single crystal of gallium oxide from a melt of the material;

then decreasing the temperature in the furnace space to 1,000° C. to 1,200° C.;

then descending the crucible toward an annealing chamber being disposed in a lower portion of the furnace space, or being disposed under the furnace body and connected to the furnace space, to carry the crucible into the annealing chamber retained to 1,000° C. to 1,200° C.; and

then annealing the crucible in the annealing chamber.

### Advantageous Effects of Invention

According to one or more aspects of the present invention, a gallium oxide crystal can be stably taken out to the outside of the apparatus by preventing the deterioration of the crystal quality due to quenching of the crucible while retaining the prescribed temperature in the furnace space for preventing the heater from being broken.

### BRIEF DESCRIPTION OF DRAWINGS

FIG. 1 is a schematic illustration (vertical cross sectional view) showing an example of a production apparatus for a gallium oxide crystal according to a first embodiment of the present invention.

FIG. 2 is a schematic illustration (vertical cross sectional view) showing an example of a production apparatus for a gallium oxide crystal according to a second embodiment of the present invention.

### Description of Embodiments

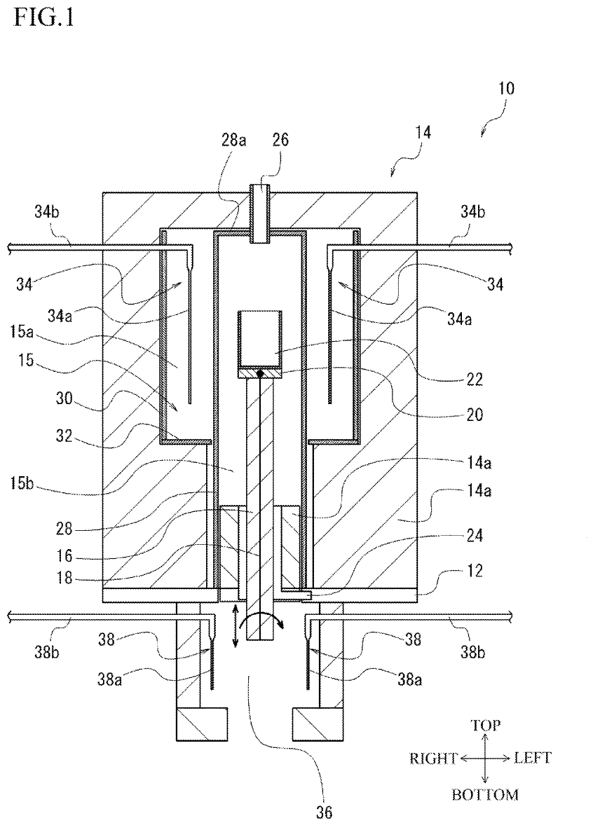

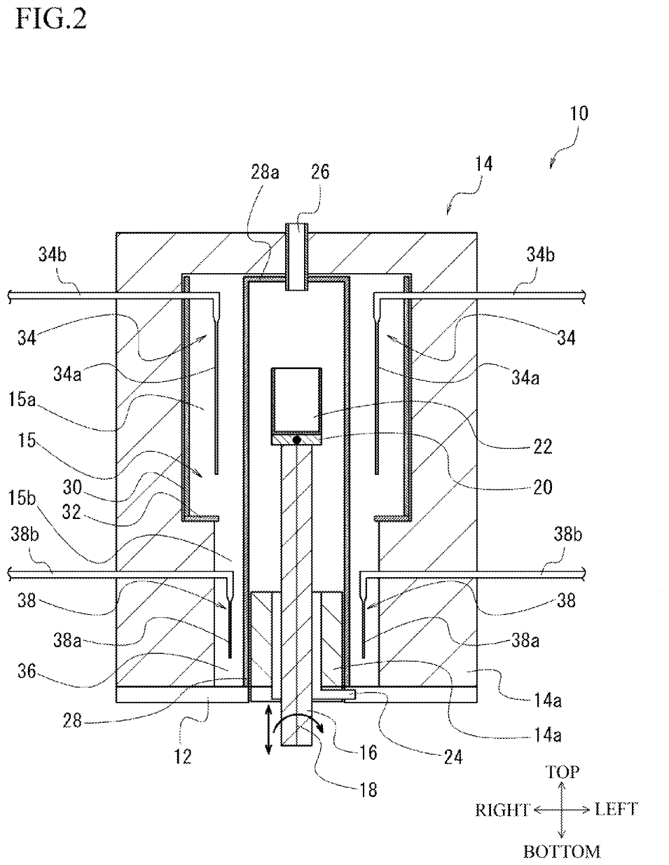

Embodiments of the present invention will be described in detail with reference to the drawings below. FIG. 1 is a schematic illustration (vertical cross sectional view) showing an example of a production apparatus for a gallium oxide crystal 10 according to a first embodiment of the present invention. FIG. 2 is a schematic illustration (vertical cross sectional view) showing an example of a production apparatus for a gallium oxide crystal 10 according to a second embodiment of the present invention. In all the figures for describing the embodiments, members having the same function are attached with the same symbol, and the repeated explanation therefor may be omitted in some cases.

### First Embodiment

The production apparatus for a gallium oxide crystal 10 (which may be hereinafter referred simply to as an apparatus 10 in some cases) according to the first embodiment of the present invention is the production apparatus 10 for a gallium oxide crystal (single crystal) using the vertical Bridgman method, in which a crucible 22 (in a furnace body 14) is heated with a body heater 34 to melt a material of a gallium oxide crystal, and crystal growth is performed by using the solidification phenomenon caused by cooling the material melt. The apparatus will be described in detail below.

The production apparatus for a gallium oxide crystal 10 shown in FIG. 1 has the furnace body 14 on a base substrate 12. The furnace body 14 includes plural ring members each having a prescribed height formed of a heat resistant material 14a, which are laminated in the vertical direction to form a cylinder shape, so as to form a furnace space 15 therein (the laminated structure of the ring members is not shown in the figures). The ring members each are detachable at a prescribed height, and the upper side thereof is enabled to open and close the furnace body 14 as an opening and closing lid (which is not shown in the figure).

The furnace space 15 has an upper portion 15a having a relatively large inner diameter and a lower portion 15b having a relatively small inner diameter, and the lower end of the upper portion 15a and the upper end of the lower portion 15b are connected to each other. The lower portion 15b is provided along the center axis in the vertical direction of the furnace body 14.

A crucible shaft 16 is extended along the center axis in the vertical direction of the furnace body 14, penetrating the base substrate 12 and the bottom portion of the furnace body 14, reaching around the height center of the upper portion 15a through the lower portion 15b of the furnace space 15. The crucible shaft 16 is provided freely movably vertically and freely rotatably with a driving mechanism, which is not shown in the figures (see the arrows in FIG. 1). A thermocouple 18 is disposed in the crucible shaft 16, so as to enable to measure the temperature of the crucible 22. The crucible shaft 16 is also formed of a heat resistant material.

An adapter 20 for supporting the crucible 22 is provided on the crucible shaft 16 (i.e., on the upper end of the crucible shaft 16), and the crucible 22 is disposed on the adapter 20. The crucible 22 for growing a β-Ga₂O₃ crystal is preferably formed of a platinum-based alloy, such as a platinum-rhodium (Pt-Rh) alloy having a rhodium (Rh) content of 10 wt % to 30 wt %. The adapter 20 is also formed of a heat resistant material.

The periphery of the crucible shaft 16 is surrounded by the ring members formed of the heat resistant material 14a from the lower end of the lower portion 15b to around the height center of the furnace space 15, and the lower portion of the furnace body 14 is thermally insulated. The crucible 22 is taken in and out from the furnace body 14 through the opening and closing lid described above under normal conditions, and under conditions with the temperature in the furnace body 14 (i.e., the furnace space 15) exceeding the prescribed temperature, the ring member is detached to open the bottom portion of the furnace body 14, and then the crucible 22 is withdrawn from (or thrusted through) the bottom portion of the furnace body 14 along with the crucible shaft 16.

An inlet pipe 24 is provided in the bottom portion of the furnace body 14 to connect the interior and the exterior of the furnace body 14. An exhaust pipe 26 is provided in the upper portion of the furnace body 14 to connect the interior and the exterior of the furnace body 14. According to the structure, the interior of the furnace body 14 may be an air atmosphere, but may be an oxidative atmosphere by positively introducing a prescribed gas through the inlet pipe 24.

A furnace core pipe 28 surrounding the crucible 22 and the crucible shaft 16 and a furnace pipe 30 surrounding the furnace core pipe 28 are provided in the furnace body 14. A body heater 34 is provided between the furnace core pipe 28 and the furnace pipe 30.

The furnace core pipe 28 includes a pipe extended from the lower end of the furnace space 15 (lower portion 15b) to the upper end of the furnace space 15 (upper portion 15a), and a top board 28a provided along the upper end surface of the furnace space 15 (upper portion 15a). According to the structure, the side and the upside of the crucible 22 and the crucible shaft 16 are covered therewith (provided that the exhaust pipe 26 penetrates through the top board 28a). The crucible 22 and the body heater 34 can be segregated from each other with the furnace core pipe 28. Accordingly, even if a part of the body heater 34 is melted at a high temperature, impurities can be prevented from being mixed into the crucible 22 (i.e., into the gallium oxide crystal to be formed).

The furnace pipe 30 is a pipe extended along the wall surface from the lower end to the upper end of the upper portion 15a of the furnace space 15, and covers the furnace core pipe 28 from around the height center to the upper most portion thereof. A supporting member 32 in a ring shape is provided on the lower end surface of the upper portion 15a of the furnace space 15 to support the furnace pipe 30. The furnace pipe 30 can block between the body heater 34 and the heat resistant material 14a constituting the outer wall of the upper portion 15a of the furnace space 15, so as to prevent the heat resistant material 14a from suffering sintering, deformation, and cracking due to heat. Furthermore, the heat from the body heater 34 can be reflected therewith to the side of the furnace core pipe 28, so as to heat the furnace space 15 (upper portion 15a), and thereby the heat can be used without waste. The furnace core pipe 28 and the furnace pipe 30 are also formed of a heat resistant material.

The body heater 34 provided between the furnace core pipe 28 and the furnace pipe 30 is a resistance heater having a heating part 34a and a conductive part 34b, and has such a structure that the heating part 34a is electrified through the conductive part 34b, and thereby the heating part 34a generates heat at a high temperature. The body heater 34 is used at a high temperature (as the melting point of β-Ga₂O₃ is approximately 1,795° C.) in the air atmosphere or an oxidative atmosphere, and therefore for example, molybdenum disilicate (MoSi₂) having a good conductivity, a high melting point, and oxidation resistance is preferably used. The material therefor preferably has heat resistance to 1,800° C. to 1,900° C., and while the heating part 34a and the conductive part 34b may be formed of the same material, they may be formed of different materials (for example, the heating part 34a may be formed of a material having heat resistance to 1,900° C., and the conductive part 34b may be formed of a material having heat resistance to 1,800° C.).

As shown in FIG. 1, the body heater 34 (including the heating part 34a and the conductive part 34b) is provided in the furnace body 14, and a part of the conductive part 34b penetrates through the furnace body 14 (heat resistant material 14a) and is connected to an external electric power source outside the furnace body 14 (the external electric power source is not shown in the figures). More specifically, the conductive part 34b penetrates through the side portion of the furnace body 14 and is bent to the vertical direction in the furnace body 14, and the heating part 34a is extended in the vertical direction at the tip of the conductive part 34b in the furnace body 14, which are thus provided in an L-shape from side view. Only two body heaters 34 symmetrically disposed are shown in FIG. 1, but in general, plural heaters are provided to surround in a circle the crucible 22 vertically moved on the center axis in the furnace body 14 (provided that the number of the heaters 34 is not particularly limited). The disposition of the body heaters 34 enables the heating parts 34a extended in the vertical direction around the crucible 22, and thereby a temperature gradient in the vertical direction with a higher temperature in the upper portion and a lower temperature in the lower portion can be formed around the crucible 22 in the furnace space 15.

A high frequency induction heater may also be used as the body heater 34 for heating the crucible 22. In this case, for example, a high frequency coil (which is not shown in the figure) is disposed around outside the furnace body 14, and a high frequency is applied to the high frequency coil, so as to generate heat from a heater (which is not shown in the figure) disposed in the furnace body 14.

As one of the features of the present embodiment, an annealing chamber 36 connected to the furnace space 15 of the furnace body 14 is provided under the furnace body 14. According to the structure, the crucible 22 can be descended through the crucible shaft 16 and carried into the annealing chamber 36 connected to the lower portion of the furnace space 15 while retaining the prescribed temperature in the furnace space 15, and the crucible 22 (gallium oxide crystal) can be annealed (gradually cooled) and then taken out to the outside of the apparatus 10. Accordingly, cracks and breakage of the crystal due to quenching of the crucible 22 can be prevented. Furthermore, quenching of the adapter 20 and the crucible shaft 16 can also be prevented, and therefore cracks and breakage thereof due to heat shock can be prevented.

An annealing heater 38 is disposed in the annealing chamber 36, and the temperature in the annealing chamber 36 can be controlled therewith. According to the structure, the temperature difference between the furnace space 15 and the annealing chamber 36 can be reduced, and thereby quenching of the crucible 22 in carrying into the annealing chamber 36 can be prevented, and simultaneously the crucible (gallium oxide crystal) can be annealed more stably at a target rate in the annealing chamber 36.

As shown in FIG. 1, the annealing heater 38 according to the present embodiment is a resistance heater including a heating part 38a and a conductive part 38b. The conductive part 38b penetrates through the side portion of the annealing chamber 36 and is bent to the vertical direction in the annealing chamber 36, and the heating part 38a is extended in the vertical direction at the tip of the conductive part 38b in the annealing chamber 36, which are thus provided in an L-shape from side view. Only two annealing heaters 38 symmetrically disposed are shown in FIG. 1, but in general, plural heaters are provided to surround in a circle the crucible 22 vertically moved on the center axis in the furnace body 14. While the annealing heater 38 has the same configuration as the body heater 34, the kind, the material, the quality of the material, and the number of the annealing heater 38 are not particularly limited, and may be appropriately configured depending on the size of the furnace body 14, the lower limit temperature of the body heater 34, and the like.

The annealing heater 38 according to the present embodiment may be formed, for example, of molybdenum disilicate (MoSi₂) as similar to the body heater 34, and a material having heat resistance to 1,500° C. to 1,700° C. may be used since the temperature of the annealing heater 38 does not become as high as the body heater 34. According to the configuration, since the SiO₂ coating formed on the surface thereof does not become so thick, and cracks and breakage are difficult to occur even in cooling after heating, the heater can be freely cooled to room temperature. Accordingly, the heater can be used for annealing the crucible 22 (gallium oxide crystal). A material having a lower melting point than molybdenum disilicate (MoSi₂) or a material having lower heat resistance may also be used.

The annealing chamber 36 according to the present embodiment is made to be an air atmosphere or an oxidative atmosphere, and as an application example, the atmosphere in the annealing chamber 36 may be changed to subject the formed gallium oxide crystal to annealing corresponding to the purpose. Production Method for Gallium Oxide Crystal

A production method for a gallium oxide crystal according to the present embodiment using the production apparatus for a gallium oxide crystal 10 according to the present embodiment will be described.

A gallium oxide crystal is produced in the furnace body 14 using the known vertical Bridgman method. Specifically, the crucible 22 housing a material of a gallium oxide crystal (crystal material), such as a sintered body of β-Ga₂O₃, and optionally a seed crystal is heated to a temperature exceeding the melting point of gallium oxide (approximately 1,795° C. for β-Ga₂O₃) with the body heater 34, so as to melt the crystal material. The crucible 22 is then descended through the crucible shaft 16, and thereby the material melt is crystallized from the lower part (the side of the seed crystal) to grow a single crystal of gallium oxide. The crucible 22 (i.e., the grown gallium oxide crystal) is then taken out to the outside of the apparatus 10 in the following manner while retaining the prescribed temperature of the body heater 34 (which is herein approximately 1,100° C. or more). Specifically, the body heater 34 is controlled to cool the furnace space 15 to the lower limit temperature of the body heater 34 (approximately 1,100° C.) or a temperature that is slightly higher or slightly lower the lower limit temperature (1,000° C. to 1,200° C.). According to the procedure, the temperature of the crucible 22 (gallium oxide crystal) is decreased by decreasing the temperature of the furnace space 15 as much as possible, and thereby the subsequent annealing time of the crucible 22 (gallium oxide crystal) can be decreased. Furthermore, the temperature of the annealing chamber 36 can be readily close to the temperature of the furnace space 15. Even though the temperature in the furnace space 15 is slightly lower than the lower limit temperature of the body heater 34, there is no problem since the body heater 34 itself is retained to a higher temperature than the furnace space 15, i.e., the lower limit temperature or higher. The crucible 22 is then descended through the crucible shaft 16, and thereby the crucible 22 is carried into the annealing chamber 36 retained to the same temperature as the furnace space 15 or a temperature close thereto (1,000° C. to 1,200° C.). According to the procedure, the temperature difference between the furnace space 15 and the annealing chamber 36 can be decreased as much as possible, and thereby quenching in carrying the crucible 22 into the annealing chamber 36 can be prevented. The crucible 22 (gallium oxide crystal) is then annealed in the annealing chamber 36 at a target rate to a target temperature (for example, room temperature or a temperature around room temperature), and then the crucible 22 is taken out from the annealing chamber 36.

According to the method, the gallium oxide crystal can be stably taken out to the outside of the apparatus 10 by preventing the deterioration of the crystal quality due to quenching of the crucible 22 while retaining the prescribed temperature in the furnace space 15 for preventing the body heater 34 from being broken. As a result, a gallium oxide crystal having stable quality can be obtained.

The method can also be applied to the production apparatus for a gallium oxide crystal 10 according to the second embodiment described below.

### Second Embodiment

Subsequently, the production apparatus for a gallium oxide crystal 10 according to the second embodiment will be described below mainly for the differences from the first embodiment. The production apparatus for a gallium oxide crystal 10 according to the present embodiment is a production apparatus for a gallium oxide crystal 10 using the vertical Bridgman method including a furnace body 14 formed of a heat resistant material, a crucible shaft 16 freely movable vertically, being extended in the furnace body 14, and penetrating through the bottom portion of the furnace body 14 in the vertical direction, a crucible 22 for housing a material of a gallium oxide crystal, being disposed on the crucible shaft 16, a body heater 34 for heating the crucible 22, being disposed around a periphery of the crucible 22, an annealing chamber 36 for annealing the crucible 22, being disposed in the lower portion 15b of the furnace space 15 in the furnace body 14, and an annealing heater 38 for annealing the crucible 22, being disposed in the annealing chamber 36.

In the first embodiment, as shown in FIG. 1, the annealing chamber 36 connected to the furnace space 15 of the furnace body 14 is disposed under the furnace body 14. On the other hand, in the present embodiment, as shown in FIG. 2, the annealing chamber 36 is provided in the lower portion 15b of the furnace space 15 of the furnace body 14. In also the structure according to the present embodiment, as similar to the first embodiment, the crucible 22 can be descended through the crucible shaft 16 and carried into the annealing chamber 36 positioned in the lower portion 15b of the furnace space 15 while retaining the prescribed temperature in the furnace space 15 (except for the annealing chamber 36), and the crucible 22 (gallium oxide crystal) can be annealed and then taken out to the outside of the apparatus 10. Accordingly, cracks and breakage of the crystal due to quenching of the crucible 22. Furthermore, quenching of the adapter 20 and the crucible shaft 16 can also be prevented, and therefore cracks and breakage thereof due to heat shock can be prevented.

Furthermore, as shown in FIG. 2, the annealing heater 38 is disposed in the annealing chamber 36 according to the present embodiment, and thereby the temperature in the annealing chamber 36 can be controlled. According to the structure, the crucible 22 (gallium oxide crystal) can be annealed more stably at a target rate in the annealing chamber 36 while retaining the prescribed temperature in the furnace space 15 (except for the annealing chamber 36). As described in the foregoing, by using the production apparatus for a gallium oxide crystal according to the present invention, a gallium oxide crystal can be stably taken out to the outside of the apparatus by preventing the deterioration of the crystal quality due to quenching of the crucible while retaining the prescribed temperature in the furnace space for preventing the heater from being broken. Furthermore, by using the production method for a gallium oxide crystal using the production apparatus according to the present invention, a gallium oxide crystal having stable quality can be obtained as a result of the above.

The present invention is not limited to the aforementioned embodiments and examples, and may be subjected to various modifications within ranges that do not deviate from the present invention.

What is claimed is:

1. A production apparatus for a gallium oxide crystal using a vertical Bridgman method comprising:
a furnace body formed of a heat resistant material;
a crucible shaft freely movable vertically, being extended in the furnace body, and penetrating through a bottom portion of the furnace body in the vertical direction;
a crucible for housing a material of a gallium oxide crystal, being disposed on the crucible shaft;
a body heater for heating the crucible, being disposed around a periphery of the crucible; and
an annealing chamber for annealing the crucible, being disposed under the furnace body, and being connected to a furnace space in the furnace body.

2. The production apparatus for a gallium oxide crystal according to claim 1, wherein
the production apparatus further comprises an annealing heater for annealing the crucible, being disposed in the annealing chamber.

3. The production apparatus for a gallium oxide crystal according to claim 2, wherein
the annealing heater is a resistance heater formed of a material having heat resistance to 1,500° C. to 1,700° C.

4. The production apparatus for a gallium oxide crystal according to claim 1, wherein the body heater is a resistance heater formed of a material having heat resistance to 1,800° C. to 1,900° C.

5. A production apparatus for a gallium oxide crystal using a vertical Bridgman method comprising:
a furnace body formed of a heat resistant material;
a crucible shaft freely movable vertically, being extended in the furnace body, and penetrating through a bottom portion of the furnace body in the vertical direction;
a crucible for housing a material of a gallium oxide crystal, being disposed on the crucible shaft;
a body heater for heating the crucible, being disposed around a periphery of the crucible;
an annealing chamber for annealing the crucible, being disposed in a lower portion of a furnace space in the furnace body; and
an annealing heater for annealing the crucible, being disposed in the annealing chamber.

6. The production apparatus for a gallium oxide crystal according to claim 5, wherein
the annealing heater is a resistance heater formed of a material having heat resistance to 1,500° C. to 1,700° C.

7. The production apparatus for a gallium oxide crystal according to claim 5, wherein the body heater is a resistance heater formed of a material having heat resistance to 1,800° C. to 1,900° C.

8. A production method for a gallium oxide crystal using a production apparatus for a gallium oxide crystal using a vertical Bridgman method, comprising:
in a furnace space of a furnace body, heating a crucible housing a material of a gallium oxide crystal to a temperature exceeding 1,795° C. to melt the material of a gallium oxide crystal, and then descending the crucible to grow a single crystal of gallium oxide from a melt of the material;
then decreasing the temperature in the furnace space to 1,000° C. to 1,200° C.;
then descending the crucible toward an annealing chamber being disposed in a lower portion of the furnace space, or being disposed under the furnace body and connected to the furnace space, to carry the crucible into the annealing chamber retained to 1,000° C. to 1,200° C.; and
then annealing the crucible in the annealing chamber.
